(19) United States
(12) Patent Application Publication
(10) Pub. No.: US 2026/0154475 A1
(43) Pub. Date: Jun. 4, 2026

(54) METHOD AND SYSTEM FOR PREDICTING BUILDING HEATING AND COOLING ELECTRICAL LOADS BASED ON TRANSFER LEARNING

(71) Applicant: SHANDONG JIANZHU UNIVERSITY, Jinan, Shandong (CN)

(72) Inventors: Yi Yan, Jinan, Shandong (CN); Chongyi Tian, Jinan, Shandong (CN); Chengdong Li, Jinan, Shandong (CN); Ruiqi Wang, Jinan, Shandong (CN); Chenlu Tian, Jinan, Shandong (CN); Zhuliang Shao, Jinan, Shandong (CN); Fan Wang, Jinan, Shandong (CN); Ji Li, Jinan, Shandong (CN); Biao Qiao, Jinan, Shandong (CN); Huiyu Xue, Jinan, Shandong (CN); Yukang Cao, Jinan, Shandong (CN)

(21) Appl. No.: 18/725,108

(22) PCT Filed: Oct. 11, 2023
(86) PCT No.: PCT/CN2023/124004

§ 371 Date: Jun. 27, 2024

(30) Foreign Application Priority Data
Oct. 11, 2022 (CN) 202211237284.7

(51) Int. Cl. G06F 30/27

(52) U.S. Cl. CPC G06F 30/27

(57) ABSTRACT

Provided is a method and system for predicting building heating and cooling electrical loads. The method includes: obtaining actual and simulated heating and cooling electrical data of a plurality of source domain buildings as well as simulated heating and cooling electrical load data of a target domain building; calculating temporal errors of heating and cooling electrical data of the plurality of source domain buildings; calculating correlation of the target domain building with the plurality of source domain buildings, and on this basis, calculating weighted errors; transferring the weighted errors to the simulated heating and cooling electrical load data of the target domain building, using heating and cooling electrical load data after the transfer as historical heating and cooling electrical load data of the target domain building; constructing and training a prediction model; and predicting heating and cooling electrical load data of the target domain building through the trained prediction model.

### CROSS REFERENCE TO RELATED APPLICATIONS

This application is a U.S. National Stage under 35 U.S.C. § 371 of International Application No. PCT/CN2023/124004 filed on Oct. 11, 2023, which claims priority to the Chinese Patent Application No. 202211237284.7 filed with the China National Intellectual Property Administration (CNIPA) on Oct. 11, 2022, and entitled “METHOD AND SYSTEM FOR PREDICTING BUILDING HEATING AND COOLING ELECTRICAL LOADS BASED ON TRANSFER LEARNING”, which is incorporated herein by reference in its entirety.

It is intended that the referenced application may be applicable to the concepts and embodiments disclosed herein, even if such concepts and embodiments are disclosed in the referenced application with different limitations and configurations and described using different examples and terminology.

### TECHNICAL FIELD

The present disclosure relates to the technical field of building electrical load prediction, and in particular to a method and system for predicting building heating and cooling electrical loads based on transfer learning.

### BACKGROUND

In recent years, with the continuous growth of the population and rapid development of science and technology, environmental and energy issues have posed huge global crises. Therefore, achieving sustainable development based on energy conservation and environmental protection is of great significance. Currently, the three main sectors of energy conservation and emission reduction are: buildings, industry, and transportation. Due to population growth, increasing demand for building services and comfort, and factors such as increased time spent in buildings, the energy consumption of buildings has surpassed that of the other two sectors. Most of the energy consumption in buildings comes from electrical loads, and with the increasing demand for the safety, stability, and economy of power systems, the importance of electrical load prediction is becoming more prominent. Electrical load prediction refers to estimating future energy demand. It is an important part of energy system operation and management, and is a necessary prerequisite for rational arrangement of power generation, transmission, and distribution, which is crucial for the development of modern energy systems. Accurate building electrical load prediction is the basis for the efficient and stable operation of power systems and is a key issue in grid energy management.

Building electrical load prediction includes predictions for building heating and cooling electrical loads. The cooling load refers to the heat that needs to be removed from a room by the air conditioning system to maintain the thermal and humidity environment of the building and the required indoor temperature, i.e., the cooling capacity required for a room at a specific moment. Conversely, if the air conditioning system needs to supply heat to the indoor space to compensate for the heat loss of the room, the heat supplied to the room is called the heating load. Currently, there are various prediction methods for building heating and cooling electrical loads, for example, predicting building electrical loads by using traditional statistical methods like autoregressive moving average models, autoregressive integrated moving average models, etc. However, when a target domain building that lacks historical heating and cooling electrical load data appears, it is difficult to accurately predict the heating and cooling electrical loads of the new building using existing deep learning-based prediction methods, thus failing to accurately estimate future energy demand. Transferring the heating and cooling electrical load data from a source domain building to a target domain building can effectively solve this key problem. However, blindly transferring heating and cooling electrical load data often results in counterproductive effects when there are many source domain buildings.

### SUMMARY

To address the shortcomings of the prior art, the present disclosure provides a method and system for predicting building heating and cooling electrical loads based on transfer learning. Weighted errors of heating and cooling electrical load data of a plurality of source domain buildings are transferred to simulated heating and cooling electrical load data of a target domain building through transfer learning. Heating and cooling electrical load data after the transfer is then used as actual historical heating and cooling electrical load data of the target domain building to train a prediction model. The load is accurately predicted by using the trained prediction model, thereby solving the problem of failing to accurately predict the load of a new building in a certain area due to the lack of historical heating and cooling electrical load data.

According to a first aspect, the present disclosure provides a method for predicting building heating and cooling electrical loads based on transfer learning.

A method for predicting building heating and cooling electrical loads based on transfer learning includes:
obtaining actual heating and cooling electrical load data of a plurality of source domain buildings, and modeling a target domain building and the plurality of source domain buildings separately to obtain simulated heating and cooling electrical load data of the target domain building and the plurality of source domain buildings;
obtaining temporal errors of the heating and cooling electrical load data of the plurality of source domain buildings based on the actual heating and cooling electrical load data and the simulated heating and cooling electrical load data of the plurality of source domain buildings;
calculating correlation of the simulated heating and cooling electrical load data of the target domain building with the simulated heating and cooling electrical load data of the plurality of source domain buildings by using a Spearman rank correlation coefficient, and calculating weighted errors of the heating and cooling electrical load data of the plurality of source domain buildings based on the correlation;
transferring the weighted errors of the heating and cooling electrical load data of the plurality of source domain buildings to the simulated heating and cooling electrical load data of the target domain building through transfer learning, and using heating and cooling electrical load data after the transfer as historical heating and cooling electrical load data of the target domain building; and
constructing and training a prediction model based on the historical heating and cooling electrical load data of the target domain building, and predicting heating and cooling electrical load data of the target domain building by using the trained prediction model.

In a further technical solution, a heating and cooling electrical load error threshold is set for the source domain buildings, and heating and cooling electrical load error data of the plurality of source domain buildings is compared with the heating and cooling electrical load error threshold to determine whether the modeling of the plurality of source domain buildings is accurate; if yes, subsequent steps are performed; and if not, re-modeling is performed until accuracy is achieved.

In a further technical solution, a correlation threshold is set, and the correlation between the simulated heating and cooling electrical load data of the plurality of source domain buildings and the simulated heating and cooling electrical load data of the target domain building is compared with the correlation threshold, to determine whether the plurality of source domain buildings meet standards for transfer learning; if yes, subsequent steps are performed; and if not, new source domain buildings are selected until the standards are met.

In a further technical solution, based on values of the correlation between the simulated heating and cooling electrical load data of the plurality of source domain buildings and the simulated heating and cooling electrical load data of the target domain building, different weights are assigned to the temporal errors of the heating and cooling electrical load data of the plurality of source domain buildings, and the temporal errors are multiplied with the corresponding weights to obtain the weighted errors of the heating and cooling electrical load data of the plurality of source domain buildings.

In a further technical solution, the weighted errors of the heating and cooling electrical load data of the plurality of source domain buildings are added directly to the simulated heating and cooling electrical load data of the target domain building, and transfer learning is performed to obtain heating and cooling electrical load data after the transfer, the number of pieces of which is equal to the number of the source domain buildings.

According to a second aspect, the present disclosure provides a system for predicting building heating and cooling electrical loads based on transfer learning.

A system for predicting building heating and cooling electrical loads based on transfer learning includes:
a data obtaining module configured to obtain actual heating and cooling electrical load data of a plurality of source domain buildings, and model a target domain building and the plurality of source domain buildings separately to obtain simulated heating and cooling electrical load data of the target domain building and the plurality of source domain buildings;
a data processing module configured to obtain temporal errors of the heating and cooling electrical load data of the plurality of source domain buildings based on the actual heating and cooling electrical load data and the simulated heating and cooling electrical load data of the plurality of source domain buildings; and calculate correlation of the simulated heating and cooling electrical load data of the target domain building with the simulated heating and cooling electrical load data of the plurality of source domain buildings by using a Spearman rank correlation coefficient, and calculate weighted errors of the heating and cooling electrical load data of the plurality of source domain buildings based on the correlation;
a historical data modeling module configured to transfer the weighted errors of the heating and cooling electrical load data of the plurality of source domain buildings to the simulated heating and cooling electrical load data of the target domain building through transfer learning, and use heating and cooling electrical load data after the transfer as historical heating and cooling electrical load data of the target domain building; and
a building heating and cooling electrical load prediction module configured to construct and train a prediction model based on the historical heating and cooling electrical load data of the target domain building, and predict heating and cooling electrical load data of the target domain building by using the trained prediction model.

In a further technical solution, a heating and cooling electrical load error threshold is set for the source domain buildings, and heating and cooling electrical load error data of the plurality of source domain buildings is compared with the heating and cooling electrical load error threshold to determine whether the modeling of the plurality of source domain buildings is accurate; if yes, subsequent steps are performed; and if not, re-modeling is performed until accuracy is achieved.

In a further technical solution, a correlation threshold is set, and the correlation between the simulated heating and cooling electrical load data of the plurality of source domain buildings and the simulated heating and cooling electrical load data of the target domain building is compared with the correlation threshold, to determine whether the plurality of source domain buildings meet standards for transfer learning; if yes, subsequent steps are performed; and if not, new source domain buildings are selected until the standards are met.

In a further technical solution, based on values of the correlation between the simulated heating and cooling electrical load data of the plurality of source domain buildings and the simulated heating and cooling electrical load data of the target domain building, different weights are assigned to the temporal errors of the heating and cooling electrical load data of the plurality of source domain buildings, to obtain the weighted errors of the heating and cooling electrical load data of the plurality of source domain buildings.

In a further technical solution, the weighted errors of the heating and cooling electrical load data of the plurality of source domain buildings are added directly to the simulated heating and cooling electrical load data of the target domain building, and transfer learning is performed to obtain the transferred heating and cooling electrical load data, the number of pieces of which is equal to the number of the source domain buildings.

One or more of the above technical solutions have the following beneficial effects:

1. The present disclosure proposes a method for predicting building heating and cooling electrical loads based on transfer learning. By taking differences between measured actual heating and cooling electrical load data of a plurality of source domain buildings and simulated heating and cooling electrical load data generated by the energy simulation software TRNSYS, temporal errors, which conform to a certain distribution, of the heating and cooling electrical load data of the source domain buildings are obtained. It is determined whether the error is lower than a set threshold. If the error is lower than the threshold, it indicates the effectiveness of the simulated data; if the error is higher than the threshold, it suggests a high error of the simulated data, and it is necessary to fine-tune the TRNSYS building model until the error is lower than the threshold. This method effectively improves the accuracy of heating and cooling electrical load prediction based on transfer learning.

2. The method of the present disclosure utilizes the Spearman rank correlation coefficient to analyze the correlation between the simulated heating and cooling electrical load data of the plurality of source domain buildings and the simulated heating and cooling electrical load data of the target domain building. It is determined whether the correlation is greater than a set threshold. If the correlation is lower than the threshold, it indicates low correlation between the source domain building and the target domain building. In this case, the target domain building and transfer learning is infeasible, the source domain building is discarded, and a new suitable source domain building is sought. If the correlation is higher than the threshold, it indicates high correlation between the source domain building and the target domain building. In this case, subsequent transfer learning can be performed, thereby further improving the accuracy of heating and cooling electrical load prediction through transfer learning.

3. Based on the values of the Spearman correlation coefficient, the method of the present disclosure assigns different weights to the temporal errors of the heating and cooling electrical load data of the source domain buildings, then transfers the weighted errors of the simulated data from the plurality of source domain buildings through transfer learning. This alleviates the problem of load mismatch caused by direct transfer of load data and solves the issue of inflexible control caused by transferring errors of heating and cooling electrical load data from a single source domain building, thus enhancing the accuracy of simulated historical data of the target domain building and consequently improving the accuracy of heating and cooling electrical load prediction for the target domain building.

4. The method of the present disclosure transfers the weighted errors of the heating and cooling electrical load data of the source domain buildings through transfer learning to the simulated heating and cooling electrical load data of the target domain building. Heating and cooling electrical load data after the transfer is then used as actual historical heating and cooling electrical load data for the target domain building to train the prediction model. By using the trained prediction model for accurate load prediction, the present disclosure addresses the issue of inaccurate load prediction for a new building in a certain area due to the lack of historical heating and cooling electrical load data.

### BRIEF DESCRIPTION OF THE DRAWINGS

Accompanying drawings of the description constitute part of the present disclosure and serve to provide further understanding of the present disclosure, and illustrative embodiments of the present disclosure and the description of the illustrative embodiments serve to explain the present disclosure and are not to be construed as unduly limiting the present disclosure.

FIG. 1 is an overall flowchart of a prediction method according to Embodiment 1 of the present disclosure; and

FIG. 2 is a flowchart of prediction using a prediction model according to Embodiment 1 of the present disclosure.

### DETAILED DESCRIPTION OF THE EMBODIMENTS

It should be pointed out that the following detailed description is illustrative and is intended to provide further description of the present disclosure. All technical and scientific terms used herein have the same meaning as commonly understood by those of ordinary skill in the art to which the present disclosure belongs unless otherwise defined.

It should be noted that terms used herein are merely for describing particular implementation modes and are not intended to limit illustrative implementation modes according to the present disclosure. As used herein, unless otherwise specified herein, the singular forms are also intended to include the plural forms. In addition, it should also be understood that when the terms “comprise” and/or “include” are used in this specification, they specify the presence of features, steps, operations, devices, components, and/or combinations thereof.

### Embodiment 1

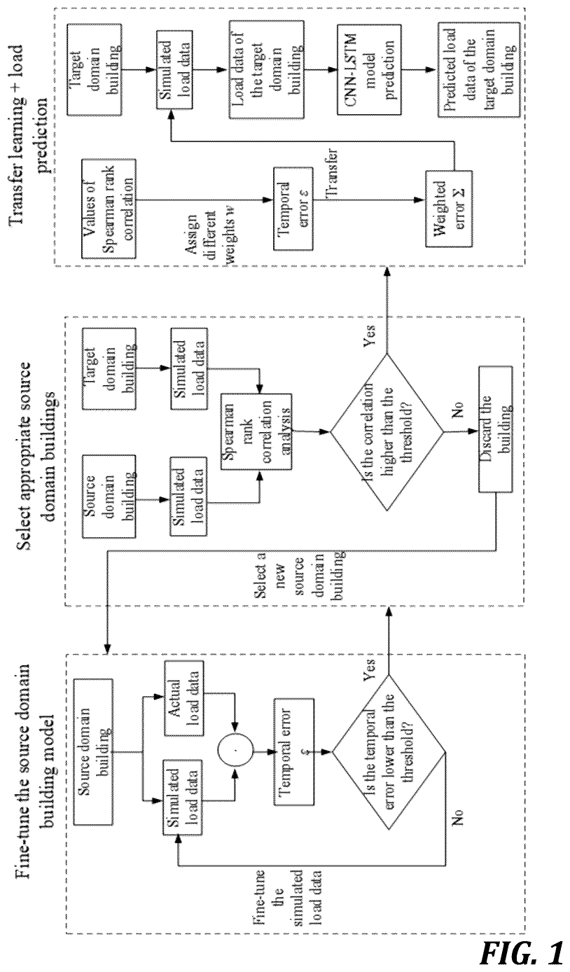

As shown in FIG. 1, this embodiment provides a method for predicting building heating and cooling electrical loads based on transfer learning, including the following steps:

Step 1: Obtain actual heating and cooling electrical load data of a plurality of source domain buildings, and model a target domain building and the plurality of source domain buildings separately to obtain simulated heating and cooling electrical load data of the target domain building and the plurality of source domain buildings.

Step 2: Obtain temporal errors of the heating and cooling electrical load data of the plurality of source domain buildings based on the actual heating and cooling electrical load data and the simulated heating and cooling electrical load data of the plurality of source domain buildings.

Step 3: Calculate correlation of the simulated heating and cooling electrical load data of the target domain building with the simulated heating and cooling electrical load data of the plurality of source domain buildings by using a Spearman rank correlation coefficient, and calculate weighted errors of the heating and cooling electrical load data of the plurality of source domain buildings based on the correlation.

Step 4: Transfer the weighted errors of the heating and cooling electrical load data of the plurality of source domain buildings to the simulated heating and cooling electrical load data of the target domain building through transfer learning, and use heating and cooling electrical load data after the transfer as historical heating and cooling electrical load data of the target domain building.

Step 5: Construct and train a prediction model based on the historical heating and cooling electrical load data of the target domain building, and predict heating and cooling electrical load data of the target domain building by using the trained prediction model.

Specifically, in this embodiment, in step 1, actual heating and cooling electrical load data of a plurality of source domain buildings is first obtained through measurements. The source domain buildings refer to buildings other than the target domain building to be predicted. The target domain building is a new building with insufficient historical heating and cooling electrical load data. Direct modeling and prediction based on this historical heating and cooling electrical load data would result in inaccurate prediction results. The source domain buildings are existing buildings relative to the target domain building, with more historical heating and cooling electrical load data.

By measuring temperatures and flow rates of incoming and outgoing water of cooling/heating equipment within the source domain buildings, and through calculations using the thermodynamic formula (1) below, the heating and cooling electrical loads of the buildings are obtained:

$$Q = cm Δ t \qquad ( 1 )$$

where Q represents heat released/absorbed, c represents the specific heat capacity of water, m represents the mass of water, and Δt represents a temperature difference between the incoming and outgoing water.

The actual heating and cooling electrical load data of the source domain buildings obtained through measurement are represented as {X₁, X₂, . . . , Xₙ}, where Xᵢ represents an actual heating and cooling electrical load dataset of the i-th source domain building, i=1, 2, . . . , n, and n represents the number of source domain buildings, as shown in formula (2):

$${X}_{i} = {[ {Q}_{i 1} , {Q}_{i 2} , … , {Q}_{it} ]}^{T} \qquad ( 2 )$$

where Qᵢₜ represents actual heating and cooling electrical load data of the i-th source domain building at time t.

At the same time, the target domain building and the source domain buildings are separately modeled to obtain simulated heating and cooling electrical load data of the target domain building and the source domain buildings. Specifically, modeling is conducted using energy simulation software TRNSYS. TRNSYS, as energy simulation software, first uses modeling software SketchUp to establish a physical model of the building. Then, the physical model is imported into TRNSYS and various thermodynamic parameters of the building are set, such as heat transfer coefficients of walls, heat transfer coefficients of glass, cooling and heating temperatures, etc. Next, electrical parameters of various electrical equipment are set. Finally, simulated heating and cooling electrical load data of the building can be obtained.

The target domain building and the source domain buildings are separately modeled using the energy simulation software TRNSYS, to obtain simulated heating and cooling electrical load data {Yₛ} of the target domain building as well as simulated heating and cooling electrical load data {Xₛ₁, Xₛ₂, . . . , Xₛₙ} of the source domain buildings, where Xₛᵢ represents a simulated heating and cooling electrical load dataset of the i-th source domain building, as shown in formula (3) and formula (4):

$${X}_{si} = {[ {Q}_{si 1} , {Q}_{si 2} , … , {Q}_{sit} ]}^{T} \qquad ( 3 )$$

$${Y}_{S} = {[ {Q}_{1} , {Q}_{2} , … , {Q}_{t} ]}^{T} \qquad ( 4 )$$

where Qₛᵢₜ represents simulated heating and cooling electrical load data of the i-th source domain building at time t, and Qₜ represents simulated heating and cooling electrical load data of the target domain building at time t.

In step 2, temporal errors of the heating and cooling electrical load data of the source domain buildings are obtained based on the actual heating and cooling electrical load data and the simulated heating and cooling electrical load data of the source domain buildings.

Specifically, by taking differences between the actual heating and cooling electrical load data of the source domain buildings obtained through measurement and the simulated heating and cooling electrical load data generated by the energy simulation software TRNSYS, the temporal errors of the heating and cooling electrical load data of the source domain buildings, following a specific distribution, are obtained. That is, based on the actual heating and cooling electrical load data {X₁, X₂, . . . , Xₙ} and the simulated heating and cooling electrical load data {Xₛ₁, Xₛ₂, . . . , Xₛₙ} of the source domain buildings, the heating and cooling electrical load data errors {ε₁, ε₂, . . . , εₙ} of the source domain buildings, following a specific distribution, are obtained by taking differences, as shown in formula (5).

$$\{ \begin{matrix}{X}_{1} - {X}_{s 1} = {ε}_{1} \\ {X}_{2} - {X}_{s 2} = {ε}_{2} \\ \begin{matrix}⋮ & ⋮ & ⋮\end{matrix} \\ {X}_{n} - {X}_{s n} = {ε}_{n}\end{matrix} \qquad ( 5 )$$

where εᵢ represents a heating and cooling electrical load error dataset of the i-th source domain building, as shown in formula (6).

$${ε}_{i} = [ Δ {ε}_{i 1} , Δ {ε}_{i 2} , … , Δ {ε}_{i t} ] \qquad ( 6 )$$

where Δeᵢₜ represents heating and cooling electrical load error data of the i-th source domain building at time t.

On this basis, in another implementation, a heating and cooling electrical load error threshold is set for the source domain buildings, and heating and cooling electrical load error data of the plurality of source domain buildings is compared with the heating and cooling electrical load error threshold to determine whether the modeling of the plurality of source domain buildings is accurate; if yes, subsequent steps are performed; and if not, re-modeling is performed until accuracy is achieved.

Specifically, it is determined whether the heating and cooling electrical load error dataset s of the source domain buildings is lower than the set the heating and cooling electrical load error threshold: if it is lower than the threshold, it indicates that the simulated heating and cooling electrical load dataset Xₛᵢ obtained through TRNSYS (Transient System Simulation Program) simulation for the source domain building is relatively accurate with a small error; if it is higher than the threshold, it indicates that the simulated heating and cooling electrical load dataset Xₛᵢ obtained through TRNSYS simulation for the source domain building is inaccurate with a large error. The building model established by TRNSYS is inaccurate. Model correction is carried out by establishing a more accurate building physical model, adjusting a building envelope structure and schedule, etc., to obtain a new simulated heating and cooling electrical load dataset Xₛᵢ until the heating and cooling electrical load error dataset s of the source domain building is lower than the threshold.

In step 3, correlation of the simulated heating and cooling electrical load data of the target domain building with the simulated heating and cooling electrical load data of the plurality of source domain buildings is calculated by using a Spearman rank correlation coefficient, and weighted errors of the heating and cooling electrical load data of the plurality of source domain buildings are calculated based on the correlation.

Specifically, the Spearman rank correlation analysis is conducted between the simulated heating and cooling electrical load data Xₛᵢ of the source domain buildings and the simulated heating and cooling electrical load data Xₜ of the target domain building. The Spearman rank correlation coefficient is used to estimate the correlation between time series X and Y The correlation between time series can be described by a monotonic function. Data xᵢ and yᵢ in two time series X and Y are sorted, and then values of positions after sorting (rank(xᵢ), rank(yᵢ)) are recorded. The value of (rank(xᵢ),rank(yᵢ)) is called the rank. The calculation formulas for the Spearman rank correlation coefficient are shown in formula (7) and formula (8).

$${d}_{i} = rank ( {X}_{i} ) - rank ( {Y}_{i} ) \qquad ( 7 )$$

$$ρ = 1 - \frac{6 {\sum }_{i = 1}^{N} {d}_{i}^{2}}{N ( {N}^{2} - 1 )} \qquad ( 8 )$$

where dᵢ is a rank difference, N is the number of pieces of data, d is a paired variable position difference after two variables are sorted separately, which is independent of specific values of the two variables, only related to the relationship between their values. The larger the Spearman rank correlation coefficient, the greater the correlation.

The correlation of the simulated heating and cooling electrical load data of the target domain building with the simulated heating and cooling electrical load data of the source domain buildings is calculated by using the Spearman rank correlation coefficient, as shown in formula (9) and formula (10).

$${d}_{t} = rank ( {X}_{sit} ) - rank ( {Y}_{st} ) t = 1 , 2 , … , N \qquad ( 9 )$$

$${ρ}_{i} = 1 - \frac{6 {\sum }_{t = 1}^{N} {d}_{t}^{2}}{N ( {N}^{2} - 1 )} i = 1 , 2 , … , n \qquad ( 10 )$$

where N is the number of pieces of data in Xₛᵢ and Yₛ, that is, the total number at time t; Xₛᵢₜ is a simulated heating and cooling electrical load dataset of the source domain building at time t; Yₛₜ is a simulated heating and cooling electrical load dataset of the target domain building at time t; dₜ is a paired variable position difference after two pieces of data are sorted separately; n is the number of the source domain buildings.

By calculating the values of the Spearman rank correlation coefficient of the heating and cooling electrical load sequences Xₛᵢ of the source domain buildings with respect to the heating and cooling electrical load data sequence Yₛ of the target domain building, the correlation between Xₛᵢ and Yₛ is determined. The larger the Spearman rank correlation coefficient, the greater the correlation.

On this basis, in another implementation, a correlation threshold is set, and the correlation between the simulated heating and cooling electrical load data of the plurality of source domain buildings and the simulated heating and cooling electrical load data of the target domain building is compared with the correlation threshold, to determine whether the plurality of source domain buildings meet standards for transfer learning; if yes, subsequent steps are performed; and if not, new source domain buildings are selected until the standards are met.

Specifically, it is determined whether the correlation between the simulated heating and cooling electrical load data Xₛᵢ of the source domain buildings and the simulated heating and cooling electrical load data Yₛ of the target domain building is higher than the set correlation threshold: if the correlation is higher than the threshold, it indicates high correlation between the heating and cooling electrical load data of the source domain building and the target domain building, making it suitable for subsequent transfer learning; if the correlation is lower than the threshold, it indicates low correlation between the source domain building and the target domain building, rendering it unsuitable for subsequent transfer learning. In this case, the building is discarded, and step 1 is performed again to find a new source domain building until the correlation exceeds the threshold, thus selecting an appropriate source domain building.

Further, based on values of the correlation between the simulated heating and cooling electrical load data of the source domain buildings and the simulated heating and cooling electrical load data of the target domain building, different weights are assigned to the temporal errors of the heating and cooling electrical load data of the source domain buildings. The higher the correlation, the larger the assigned weight. In this way, the weighted errors of the heating and cooling electrical load data of the source domain buildings are obtained.

Specifically, based on the values of the correlation between the simulated heating and cooling electrical load data Xₛᵢ of the source domain buildings and the simulated heating and cooling electrical load data Yₛ of the target domain, weights {w₁, w₂, . . . , wₙ} are assigned to the heating and cooling electrical load data errors {ε₁, ε₂, . . . , εₙ} of the source domain buildings, to obtain weighted errors {w₁*ε₁, w₂*ε₂, . . . , wₙ*εₙ} of the heating and cooling electrical load data of the source domain buildings. Here, wᵢ represents the weight of the heating and cooling electrical load data error set εᵢ of the i-th source domain building, and wᵢ*εᵢ represents the weighted error dataset of the heating and cooling electrical load data of the i-th source domain building. Additionally, the higher the correlation between Xₛᵢ and Yₛ, the larger the value of wᵢ, and the condition w₁+w₂+ . . . +wₙ=1 is satisfied.

In step 4, the weighted errors of the heating and cooling electrical load data of the source domain buildings are transferred to the simulated heating and cooling electrical load data of the target domain building through transfer learning, and heating and cooling electrical load data after the transfer is used as historical heating and cooling electrical load data of the target domain building.

Specifically, the weighted errors {w₁*ε₁, w₂*ε₂, . . . , wₙ*εₙ} of the heating and cooling electrical load data of the source domain buildings obtained in step 3 are transferred to the simulated heating and cooling electrical load data {Yₛ} of the target domain building through transfer learning. That is, each of the weighted errors {w₁*ε₁, w₂*ε₂, . . . , wₙ*εₙ} of the heating and cooling electrical load data of the source domain buildings is directly added to the simulated heating and cooling electrical load data {Yₛ} of the target domain building to perform transfer learning, thereby obtaining heating and cooling electrical load data after the transfer, the number of pieces of which is equal to the number of source domain buildings (i.e., n), and the heating and cooling electrical load data after the transfer is used as historical heating and cooling electrical load data of the target domain building.

In transfer learning, the subject of learning is called a domain (D), which consists of two parts: source domain (s) and target domain (t); the target of learning in transfer learning is called a task (T), which consists of two parts: label space (Y) and learning function (f).

Given the source domain Dₛ and the source task Tₛ, as well as the target domain Dₜ and the target task Dₜ, the goal of transfer learning is to utilize the knowledge of Dₛ and Tₛ to enhance the prediction performance of the learning function ƒₜ(⋅) of Tₜ when Dₛ≠Dₜ or Tₛ≠Tₜ.

In step 5, a prediction model is constructed and trained based on the historical heating and cooling electrical load data of the target domain building, and heating and cooling electrical load data of the target domain building is predicted by using the trained prediction model.

The historical heating and cooling electrical load data of the target domain building calculated in the foregoing step is used as a sample set. The sample set is divided into a training and a test set proportionally. The training set is used for training the load prediction model, while the test set is used for evaluating the accuracy of prediction results of the model. Subsequently, data of the training set is inputted into a convolutional neural network-long short-term memory (CNN-LSTM) model.

In this embodiment, the prediction model described above employs a CNN-LSTM model. The convolutional neural network (CNN) includes a feature extractor consisting of convolutional layers and sub-sampling layers (i.e., pooling layers). In the convolutional layers of the CNN, each neuron is connected to only a subset of neighboring neurons. Each convolutional layer in the CNN consists of several convolutional units, and parameters of each convolutional unit are optimized through backpropagation algorithms. The purpose of convolutional operations is to extract different features from the input. The first convolutional layer may only extract low-level features such as edges, lines, and corners, while deeper layers of the network can iteratively extract more complex features from the low-level features.

Typically, after the convolutional layers, large-dimensional features are obtained. The pooling layers divide the features into several regions and take maximum or average values, to obtain new, smaller-dimensional features. Finally, the fully connected layer combines all local features into a global feature to calculate a final score of each category.

The Long Short-Term Memory (LSTM) network is a type of recurrent neural network designed to overcome the problems of vanishing and exploding gradients during training of long sequences. The LSTM structure mainly consists of input gates, forget gates, output gates, and internal memory cells.

The forget gate controls whether to forget, and in LSTM, it controls whether to forget the hidden cell state of the previous layer with a specific probability. The input includes the hidden state h^{(t-1)} of the previous sequence and the current sequence data x^{t}. The output ƒ^{(t)} of the forget gate is obtained through a sigmoid activation function. The output also represents the probability of forgetting the hidden cell state of the previous layer, as shown in formula (11).

$${f}^{( t )} = σ ( {W}_{f} \cdot {h}^{( t - 1 )} + {U}_{f} {x}^{( t )} + {b}_{f} ) \qquad ( 11 )$$

where W_{f}, U_{f}, and b_{f} are the coefficients and bias of the linear relationship, and σ is the sigmoid activation function.

The input gate mainly processes the input at the current sequence position and mainly consists of two parts: a sigmoid activation function and a tanh activation function. The results of the two parts are multiplied to update the cell state, specifically as shown in formula (12) and formula (13).

$${i}^{( t )} = σ ( {W}_{i} {h}^{( t - 1 )} + {U}_{i} {x}^{( t )} + {b}_{i} ) \qquad ( 12 )$$

$${a}^{( t )} = tanh ( {W}_{a} {h}^{( t - 1 )} + {U}_{a} {x}^{( t )} + {b}_{a} ) \qquad ( 13 )$$

where Wᵢ, Uᵢ, bᵢ, Wₐ, Uₐ, and bₐ are coefficients and biases of the linear relationships, and σ and tanh are activation functions.

The internal memory cell consists of two parts: the first part is the product of the previous cell state and the output of the forget gate, and the second part is the product of the input gate, specifically as shown in formula (14).

$${C}^{( t )} = {C}^{( t - 1 )} ▯ {f}^{( t )} + {i}^{( t )} ▯ {a}^{( t )} \qquad ( 14 )$$

where ⊙ denotes a Hadamard product.

The output gate consists mainly of two parts: the first part includes the hidden state of the previous sequence, the current sequence data, and the sigmoid activation function, while the second part consists of the hidden state and the tanh activation function, specifically as shown in formula (15) and formula (16).

$${o}^{( t )} = σ ( {W}_{o} {h}^{( t - 1 )} + {U}_{o} {x}^{( t )} + {b}_{o} ) \qquad ( 15 )$$

$${h}^{( t )} = {o}^{( t )} ▯ tanh ( {C}^{( t )} ) \qquad ( 16 )$$

This embodiment adopts the CNN-LSTM model. In CNN-LSTM, the CNN framework composed of convolutional layers and pooling layers automatically extracts internal features of the data. The convolutional layers perform effective nonlinear local feature extraction on the data, while the pooling layers employs the maximum pooling method to compress the extracted features and generate more crucial feature information. The LSTM hidden layer models and learns internal dynamic changes of the local features extracted by CNN, iteratively extracting more complex global features from the local features. The fully connected layer combines the extracted features from earlier stages and outputs a final prediction result.

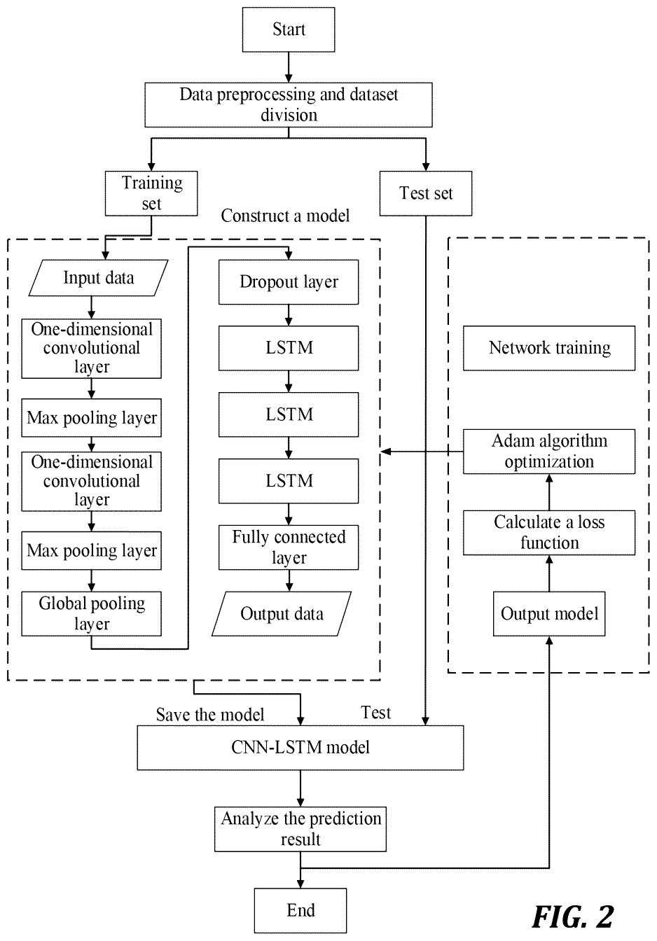

As shown in FIG. 2, the CNN-LSTM model mainly consists of two one-dimensional CNN network layers and three LSTM structure layers. The CNN network mainly includes one-dimensional convolutional layers, max-pooling layers, and a global pooling layer. The convolutional layers are used to extract effective nonlinear local features from the load dataset, while the pooling layers compress the local features extracted by the convolutional layers using the maximum pooling method, and generate more crucial feature information. Then, the global pooling layer outputs the feature extraction results of the load dataset as input to the LSTM. A Dropout layer is added before the LSTM network to randomly drop 25% of neurons during each data training iteration, aiming to prevent overfitting. The inclusion of the dropout layer effectively enhances the generalization capability and reduces the training time of the model. The LSTM network models and learns the internal dynamic changes of the local feature information extracted by the CNN network in the hidden layers, and performs iterations continuously to obtain more complex global features.

In network parameter optimization, an Adam optimizer is used to optimize the parameters of each layer of the network. Finally, the trained CNN-LSTM model is saved, and the performance of this model is tested using the test set to complete the training of the load prediction model. With the trained prediction model, the heating and cooling electrical load data of the target domain building is predicted to obtain an accurate load prediction result.

Through the above solution, the method for predicting building heating and cooling electrical loads based on transfer learning in this embodiment transfers the weighted errors of the heating and cooling electrical load data of the source domain buildings through transfer learning to the simulated heating and cooling electrical load data of the target domain building. Heating and cooling electrical load data after the transfer is then used as actual historical heating and cooling electrical load data for the target domain building to train the prediction model. By using the trained prediction model for accurate load prediction, this method addresses the issue of inaccurate load prediction for a new building in a certain area due to the lack of historical heating and cooling electrical load data.

### Embodiment 2

This embodiment provides a system for predicting building heating and cooling electrical loads based on transfer learning, including:
a data obtaining module configured to obtain actual heating and cooling electrical load data of a plurality of source domain buildings, and model a target domain building and the plurality of source domain buildings separately to obtain simulated heating and cooling electrical load data of the target domain building and the plurality of source domain buildings;
a data processing module configured to obtain temporal errors of the heating and cooling electrical load data of the plurality of source domain buildings based on the actual heating and cooling electrical load data and the simulated heating and cooling electrical load data of the plurality of source domain buildings; and calculate correlation of the simulated heating and cooling electrical load data of the target domain building with the simulated heating and cooling electrical load data of the plurality of source domain buildings by using a Spearman rank correlation coefficient, and calculate weighted errors of the heating and cooling electrical load data of the plurality of source domain buildings based on the correlation;
a historical data modeling module configured to transfer the weighted errors of the heating and cooling electrical load data of the plurality of source domain buildings to the simulated heating and cooling electrical load data of the target domain building through transfer learning, and use heating and cooling electrical load data after the transfer as historical heating and cooling electrical load data of the target domain building; and
a building heating and cooling electrical load prediction module configured to construct and train a prediction model based on the historical heating and cooling electrical load data of the target domain building, and predict heating and cooling electrical load data of the target domain building by using the trained prediction model.

The steps involved in Embodiment 2 correspond to the method in Embodiment 1. For specific implementations, refer to related descriptions in Embodiment 1.

Those skilled in the art should know that the modules or steps of the disclosure may be implemented by a universal computer device. Optionally, the modules or steps may be implemented by programmable code executable by a computing device, so that the modules or steps can be stored in a storage device for execution by the computing device. Alternatively, the modules or steps may be made into integrated circuit modules respectively, or some of the modules or steps may be made into a single integrated circuit module. The present disclosure is not limited to any specific hardware and software combination.

What are described above are merely preferred embodiments of the present disclosure and are not intended to limit the present disclosure, and for those skilled in the art, the present disclosure can be variously modified and changed. Any modification, equivalent substitution, improvement, etc. within the spirit and principles of the present disclosure shall fall within the scope of protection of the present disclosure.

The above describes the specific implementations of the present disclosure with reference to the accompanying drawings, but is not intended to limit the protection scope of the present disclosure. Those skilled in the art should understand that any modifications or variations made by those skilled in the art based on the technical solutions of the present disclosure without creative efforts still fall within the protection scope of the present disclosure.

What is claimed is:

1. A method for predicting building heating and cooling electrical loads based on transfer learning, comprising:
obtaining actual heating and cooling electrical load data of a plurality of source domain buildings, and modeling a target domain building and the plurality of source domain buildings separately to obtain simulated heating and cooling electrical load data of the target domain building and the plurality of source domain buildings;
obtaining temporal errors of the heating and cooling electrical load data of the plurality of source domain buildings based on the actual heating and cooling electrical load data and the simulated heating and cooling electrical load data of the plurality of source domain buildings;
calculating correlation of the simulated heating and cooling electrical load data of the target domain building with the simulated heating and cooling electrical load data of the plurality of source domain buildings by using a Spearman rank correlation coefficient, and calculating weighted errors of the heating and cooling electrical load data of the plurality of source domain buildings based on the correlation;
transferring the weighted errors of the heating and cooling electrical load data of the plurality of source domain buildings to the simulated heating and cooling electrical load data of the target domain building through transfer learning, and using heating and cooling electrical load data after the transfer as historical heating and cooling electrical load data of the target domain building; and
constructing and training a prediction model based on the historical heating and cooling electrical load data of the target domain building, and predicting heating and cooling electrical load data of the target domain building by using the trained prediction model.

2. The method for predicting building heating and cooling electrical loads based on transfer learning according to claim 1, wherein a heating and cooling electrical load error threshold is set for the source domain buildings, and heating and cooling electrical load error data of the plurality of source domain buildings is compared with the heating and cooling electrical load error threshold to determine whether the modeling of the plurality of source domain buildings is accurate; if yes, subsequent steps are performed; and if not, re-modeling is performed until accuracy is achieved.

3. The method for predicting building heating and cooling electrical loads based on transfer learning according to claim 1, wherein a correlation threshold is set, and the correlation between the simulated heating and cooling electrical load data of the plurality of source domain buildings and the simulated heating and cooling electrical load data of the target domain building is compared with the correlation threshold, to determine whether the plurality of source domain buildings meet standards for transfer learning; if yes, subsequent steps are performed; and if not, new source domain buildings are selected until the standards are met.

4. The method for predicting building heating and cooling electrical loads based on transfer learning according to claim 1, wherein based on values of the correlation between the simulated heating and cooling electrical load data of the plurality of source domain buildings and the simulated heating and cooling electrical load data of the target domain building, different weights are assigned to the temporal errors of the heating and cooling electrical load data of the plurality of source domain buildings, and the temporal errors are multiplied with the corresponding weights to obtain the weighted errors of the heating and cooling electrical load data of the plurality of source domain buildings.

5. The method for predicting building heating and cooling electrical loads based on transfer learning according to claim 1, wherein the weighted errors of the heating and cooling electrical load data of the plurality of source domain buildings are added directly to the simulated heating and cooling electrical load data of the target domain building, and transfer learning is performed to obtain the heating and cooling electrical load data after the transfer, the number of pieces of which is equal to the number of the source domain buildings.

6. A system for predicting building heating and cooling electrical loads based on transfer learning, comprising: a data obtaining module configured to obtain actual heating and cooling electrical load data of a plurality of source domain buildings, and model a target domain building and the plurality of source domain buildings separately to obtain simulated heating and cooling electrical load data of the target domain building and the plurality of source domain buildings;
a data processing module configured to obtain temporal errors of the heating and cooling electrical load data of the plurality of source domain buildings based on the actual heating and cooling electrical load data and the simulated heating and cooling electrical load data of the plurality of source domain buildings; and calculate correlation of the simulated heating and cooling electrical load data of the target domain building with the simulated heating and cooling electrical load data of the plurality of source domain buildings by using a Spearman rank correlation coefficient, and calculate weighted errors of the heating and cooling electrical load data of the plurality of source domain buildings based on the correlation;
a historical data modeling module configured to transfer the weighted errors of the heating and cooling electrical load data of the plurality of source domain buildings to the simulated heating and cooling electrical load data of the target domain building through transfer learning, and use heating and cooling electrical load data after the transfer as historical heating and cooling electrical load data of the target domain building; and
a building heating and cooling electrical load prediction module configured to construct and train a prediction model based on the historical heating and cooling electrical load data of the target domain building, and predict heating and cooling electrical load data of the target domain building by using the trained prediction model.

7. The system for predicting building heating and cooling electrical loads based on transfer learning according to claim 6, wherein a heating and cooling electrical load error threshold is set for the source domain buildings, and heating and cooling electrical load error data of the plurality of source domain buildings is compared with the heating and cooling electrical load error threshold to determine whether the modeling of the plurality of source domain buildings is accurate; if yes, subsequent steps are performed; and if not, re-modeling is performed until accuracy is achieved.

8. The system for predicting building heating and cooling electrical loads based on transfer learning according to claim 6, wherein a correlation threshold is set, and the correlation between the simulated heating and cooling electrical load data of the plurality of source domain buildings and the simulated heating and cooling electrical load data of the target domain building is compared with the correlation threshold, to determine whether the plurality of source domain buildings meet standards for transfer learning; if yes, subsequent steps are performed; and if not, new source domain buildings are selected until the standards are met.

9. The system for predicting building heating and cooling electrical loads based on transfer learning according to claim 6, wherein based on values of the correlation between the simulated heating and cooling electrical load data of the plurality of source domain buildings and the simulated heating and cooling electrical load data of the target domain building, different weights are assigned to the temporal errors of the heating and cooling electrical load data of the plurality of source domain buildings, and the temporal errors are multiplied with the corresponding weights to obtain the weighted errors of the heating and cooling electrical load data of the plurality of source domain buildings.

10. The system for predicting building heating and cooling electrical loads based on transfer learning according to claim 6, wherein the weighted errors of the heating and cooling electrical load data of the plurality of source domain buildings are added directly to the simulated heating and cooling electrical load data of the target domain building, and transfer learning is performed to obtain the heating and cooling electrical load data after the transfer, the number of pieces of which is equal to the number of the source domain buildings.
